(19) United States
(12) Patent Application Publication
(10) Pub. No.: US 2009/0236623 A1
(43) Pub. Date: Sep. 24, 2009

(54) Light emitting diode device

(76) Inventors: Chen-Lun Hsing Chen, Taoyuan Hsien (TW); Hsu-Keng Tseng, Taoyuan Hsien (TW); Jung-Hao Hung, Taoyuan Hsien (TW); Fong-Luan Lee, Taoyuan Hsien (TW)

Correspondence Address: TROXELL LAW OFFICE PLLC, SUITE 1404, 5205 LEESBURG PIKE, FALLS CHURCH, VA, 22041, US

(21) Appl. No.: 12/076,488

(22) Filed: Mar. 19, 2008

(51) Int. Cl. H01L 33/00

(52) U.S. Cl. 257/98; 257/E33.058; 257/E33.061; 257/E33.072

(57) ABSTRACT

A light emitting diode device includes a substrate, a reflector cup, a light emitting diode chip, and a phosphor paste. The reflector cup is set on the substrate, and has a wall of a first length and a first height wherein the first length is defined by a corresponding inner edge thereof. The LED chip is mounted on the substrate, and comprises a second length and a second height. The phosphor paste covers on the LED chip. The first height of the wall and the second height of the LED chip has a first ratio, and the first length of the wall and the second length of the LED chip has a second ratio wherein the first ratio is larger than the second ratio.

### BACKGROUND

1. Field of Invention

The present invention relates to a light emitting diode device, and more particularly to a light emitting diode device with evenly radiated light color.

2. Description of Related Art

Blue light emitting diode (LED) chips are coated with phosphor paste such that the blue light is mixed with the illuminated light from the phosphor paste to generate a fluorescent cool-white light which is visible to the human eye.

With regard to conventional lens package technology for an LED, the phosphor paste fills the reflector cup in which the blue light emitting diode chip is mounted. However, the reflector cup shape is mostly designed for the reflecting light without considering the radiated color after light reflection.

Hence, the phosphor paste is unevenly spread on the blue LED chip and results in various light colors illuminating from the respective area with different epoxy thickness. Generally speaking, the illuminated light color is close to blue because the thin covered epoxy has shorter blue light transmission path and less probability for the blue light being received and radiated by the phosphor paste. In contrast, the illuminated light color is close to yellow when the covered epoxy is thick. As a result, the light is radiated with uneven colors.

Another conventional lens package technology including the combination of the pattern and the electrophoretic deposition (EPD) method is also applied to fill the blue LED chip with phosphor paste. Through this technology, the thickness of the phosphor paste can be controlled within a predetermined range precisely, and within a 10-percentage variation range.

With respect to the luminous energy for a conventional LED chip, the front luminous energy is larger than the flank luminous energy such that the phosphor paste at the front of the chip needs to be spread thicker than the phosphor past on the sides of the chip to provide a uniform white light appearance. Nevertheless, the spread thickness is limited within 10-percentage variation range, and the radiated light with uneven colors problem cannot be solved with this technology.

Moreover, the method of applying the pattern technology to package the phosphor paste is preferably suitable for a flip chip type light emitting diode, but not acceptable to a wire bonding type light emitting diode because the pattern will damage the wires soldered on the chip. In addition, the electrophoretic deposition (EPD) technology needs extra facilities and advanced processes that increase production cost.

As a result, providing a light emitting diode device with even radiated light color and simplified fabrication processes to satisfy the needs of various lamps becomes the aim of the present invention.

### SUMMARY

It is therefore an aspect to provide a light emitting diode device with evenly radiated light color.

In accordance with an embodiment of the present invention, the light emitting diode device includes an LED chip, a reflector cup, a substrate, and a phosphor paste wherein the reflector cup is set on the substrate. The reflector cup includes a wall defining a room in which the LED chip is mounted and filled with phosphor paste to cover the LED chip. The phosphor paste includes paste and phosphorus being held in the paste whereby the LED chip emits fluorescent light through the phosphorus.

The height between the wall and the LED chip have a first predetermined proportion, and the distances between the corresponding inner edges and the LED chip also have a second predetermined proportion wherein the first predetermined proportion is larger than the second predetermined proportion.

As a result, the light emitting diode device of the present invention has the following effects:

1. Because the first predetermined proportion is larger than the second predetermined proportion, the phosphor paste at the front of the LED chip is thicker than the phosphor paste on the sides of the LED chip to provide a uniform radiated light color.

2. Compared with the conventional technology that can only be applied to the flip chip type light emitting diode, or that needs extra facilities and advanced process, the wall and the reflector cup of the light emitting diode device in accordance with the present invention can be formed by extrusion or injection molding process to reduce the production cost.

3. The wall includes the same contour with enlarged proportion as the LED chip as viewed from their tops such that the phosphor paste can be evenly spread on the LED chip through the restriction of the wall after injecting the phosphor paste into the room defined by the wall.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a top view of a light emitting diode device of a first embodiment in accordance with the present invention;

FIG. 2 is a sectional view of the light emitting diode device of the first embodiment in accordance with FIG. 1; and

FIG. 3 is a sectional view of the light emitting diode device of a second embodiment in accordance with the present invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

While the specification concludes with claims defining the features of the invention that are regarded as novel, it is believed that the invention will be better understood from a consideration of the following description in conjunction with the figures, in which like reference numerals are carried forward.

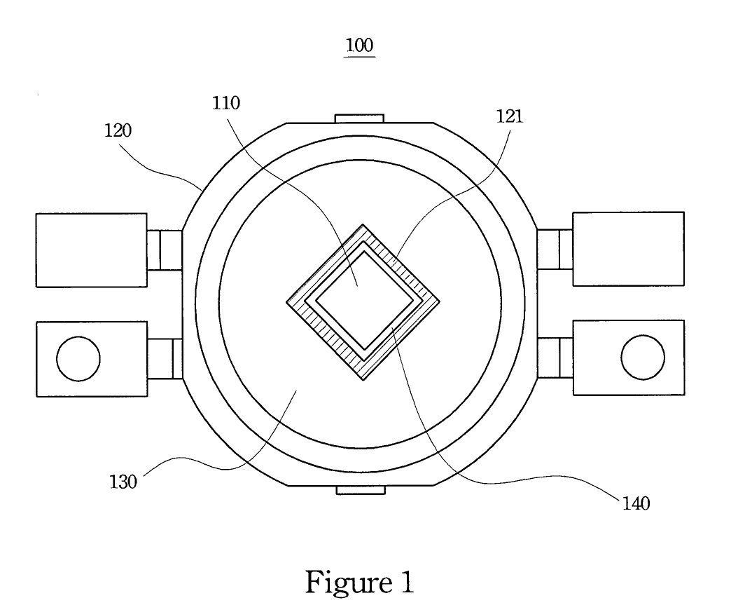

Refer to FIG. 1. FIG. 1 illustrates a top view of a light emitting diode device of a first embodiment in accordance with the present invention. The light emitting diode device 100 includes a LED chip 110, a reflector cup 120, a substrate 130, and a phosphor paste 140 wherein the reflector cup 120 is set on the substrate 130. The reflector cup 120 includes a wall 121 defining a room in which the LED chip 110 is mounted.

The wall 121 and the LED chip 110 have the same contour as viewed from their tops wherein the contour of the wall 121 is an enlarged proportion to the contour of the LED chip 110. In this configuration, the gap between the LED chip 110 and the wall 121 can be filled with the phosphor paste 140 when the phosphor paste 140 is injected into the room defined by the wall 121 to cover the LED chip 110.

In one of the embodiments, the LED chip 110 includes a top plane in the form of a first rectangle composed of a first length and a first width, and the wall 121 includes an inner edge in the form of a second rectangle composed of a second length and a second width. The corresponding first length and the second length define a first distance there between, and the corresponding first width and the second width define a second distance there between wherein the first distance is identical to the second distance.

In another of the embodiments, the LED chip 110 includes a top plane in the form of a first square, and the wall 121 includes an inner edge in the form of a second square wherein the perimeter of the second square is a proportional extension of that of the first square.

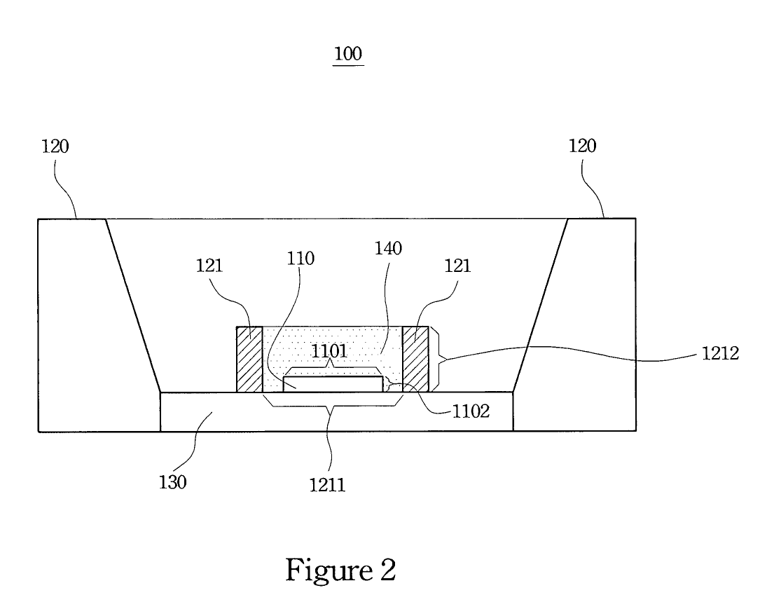

Refer to FIG. 2. FIG. 2 illustrates a sectional view of the light emitting diode device of the first embodiment in accordance with FIG. 1.

The reflector cup 120 is made of metal, plastic, glass or other transparent materials. The wall 121 includes a first space 1211 defined by the corresponding inner edges of the wall 121, and a second space 1212 defined by the top and the bottom of the wall 121. The LED chip 110 includes a third space 1101 defined by the opposite outer edges of the LED chip 110, and a fourth space 1102 defined by the top and the bottom of the LED chip 110. The first space 1211 is 1.15 to 2 multiple of the third space 1101, and the second space 1212 is 2 to 5 multiple of the fourth space 1102.

In addition, the second space 1212 and the fourth space 1102 has a first ratio in the range between 2 to 5, and the first space 1211 and the third space 1101 has a second ratio in the range between 1.15 to 2.

The phosphor paste 140 includes paste and phosphorus being held in the paste whereby the LED chip 110 emits the fluorescent light (such as yellow, red or green light) through the phosphorus. Partial light beams emitted from the LED chip 110 are reflected by the inner side of the wall 121 because the inner side of the wall 121 is parallel to the flank of the LED chip 110. Consequently, the reflected light beam is fully absorbed by the phosphorus to generate the light color complementary to original color of the LED chip 110.

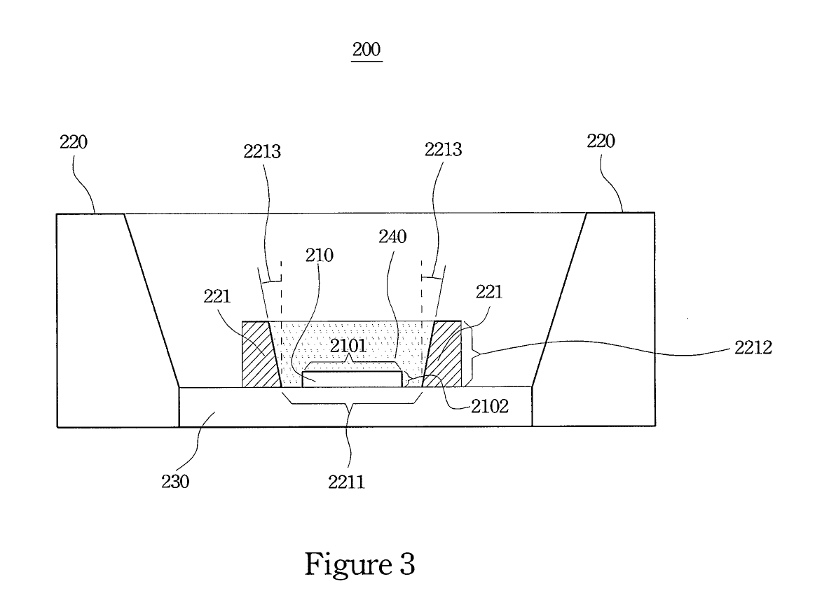

Refer to FIG. 3. FIG. 3 illustrates a sectional view of the light emitting diode device of a second embodiment in accordance with the present invention.

In the second embodiment, the light emitting diode device 200 includes an LED chip 210, a reflector cup 220, a substrate 230, and a phosphor paste 240 wherein the configuration of the above members is identical to that of the first embodiment, so there is no more description herein.

In addition, the spaces 2211, 2212, 2101, and 2102 are also identical to the first space 1211, the second space 1212, the third space 1101, and the fourth space 1102, and the ratios between the space 2212 and the space 2102, and between the space 2211 and the space 2101 are respectively identical to the first ratio and the second ratio illustrated in the first embodiment.

The difference between the first embodiment and the second embodiment is that the inner side of the wall 221 in the second embodiment is a bevel thereby forming an angle 2213 between the dotted line perpendicular to the top of the LED chip 210 and the bevel. The angle 2213 has a range between 0 degrees and 10 degrees. Consequently, partial light beam emitted from the LED chip 210 is reflected by the inner side of the wall 221 in the form of bevel to be fully absorbed by the phosphorus of the phosphor paste 240 to generate the light color complementary to original color of the LED chip 210.

Although the present invention has been described in considerable detail with reference to certain preferred embodiments thereof, other embodiments are possible. Therefore, the spirit and scope of the appended claims should not be limited to the description of the preferred embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A light emitting diode (LED) device, comprising:
a substrate;
a reflector cup set on the substrate, and comprising:
a wall with an inner edge having a first length and a first height;
an LED chip mounted on the substrate, and comprising an outer edge having a second length and a second height; and
a phosphor paste covering on the LED chip;
wherein the first height of the wall and the second height of the LED chip has a first ratio, and the first length of the wall and the second length of the LED chip has a second ratio wherein the first ratio is larger than the second ratio.

2. The light emitting diode device of claim 1, wherein the first ratio comprises a first range between 2 to 5.

3. The light emitting diode device of claim 1, wherein the second ratio comprises a second range between 1.15 to 2.

4. The light emitting diode device of claim 1, wherein the wall comprises an interior surface perpendicular to the substrate.

5. The light emitting diode device of claim 1, wherein the wall comprises an interior surface inclined to the substrate to provide an angle.

6. The light emitting diode device of claim 5, wherein the angle comprises a range between 0 degrees to 10 degrees.

7. The light emitting diode device of claim 1, wherein the LED chip is a rectangular LED chip comprising a first side and a second side, and the wall comprises a rectangular inner edge comprising a third side and a fourth side wherein a first distance between the first side and the third side is equal to a second distance between the second side and the fourth side.

8. The light emitting diode device of claim 1, wherein the LED chip is a square LED chip of a first perimeter, and the wall comprises a square inner edge of a second perimeter wherein the second perimeter is a proportional extension of the first perimeter.

9. The light emitting diode device of claim 1, wherein the reflector cup is made of metal, plastic, glass or other transparent materials.
